(19) United States
(12) Patent Application Publication
(10) Pub. No.: US 2024/0087924 A1
(43) Pub. Date: Mar. 14, 2024

(54) Multi-chamber Configuration

(71) Applicant: HINE AUTOMATION, LLC, St. Petersburg, FL (US)

(72) Inventor: Joseph Arthur Kraus, Brandon, FL (US)

(73) Assignee: HINE AUTOMATION, LLC, St. Petersburg, FL (US)

(21) Appl. No.: 18/137,855

(22) Filed: Apr. 21, 2023

Related U.S. Application Data
(60) Provisional application No. 63/405,800, filed on Sep. 12, 2022.

(51) Int. Cl. H01L 21/67; C23C 14/56; H01L 21/677

(52) U.S. Cl. CPC H01L 21/67201; C23C 14/566; C23C 14/568; H01L 21/67184; H01L 21/67742

(57) ABSTRACT

The present invention provides a multi-chamber plasma processing system. A load lock chamber having an atmospheric gate valve and a vacuum gate valve is operatively connected to a transport chamber through the vacuum gate valve. A process chamber is mounted on the load lock chamber wherein the process chamber has only one gate valve that is positioned between the transport chamber and the process chamber. The process chamber does not have an atmospheric gate valve. A substrate handling robot is mounted within the transport chamber and operatively communicates with the load lock chamber through the vacuum gate valve and operatively communicates with the process chamber through the only gate valve of the process chamber.

### CROSS REFERENCES TO RELATED APPLICATIONS

This application claims priority from and is related to commonly owned U.S. Provisional Patent Application Ser. No. 63/405,800 filed Sep. 12, 2022, entitled: Improved Multi-Chamber Configuration, this Provisional Patent Application incorporated by reference herein.

### FIELD OF THE INVENTION

The present invention relates to a multi-chamber system and, more particularly, to a multi-chamber plasma process system in which process chambers are vertical and horizontal to a load lock chamber.

### BACKGROUND OF THE INVENTION

As is well known in the semiconductor industry for manufacturing semiconductor integrated circuitry or liquid crystal displays, a multi-chamber system is used to enhance productivity. The traditional multi-chamber system is a structure wherein a number of process chambers are arranged in a cluster type formation around a transfer chamber that is also connected to a load lock chamber. A robotic arm is positioned within the transfer chamber and is integral to the load lock chamber and each of the process chambers. The robotic arm transfers the substrate into and out of the process chambers and into and out of the load lock chambers. In the current semiconductor industry, there is a need to increase process chamber capacity on existing multi-chamber systems without increasing the use of the existing floor space.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

Another feature of the present invention is to provide a multi-chamber plasma processing system, comprising: a load lock chamber having a vacuum gate valve and an atmospheric gate valve; a first process chamber mounted on the load lock chamber, said first process chamber having a single gate valve; a transport chamber, said transport chamber operatively connected to the vacuum gate valve of the load lock chamber and operatively connected to the gate valve of the transport chamber; and a substrate handling robot mounted within the transport chamber.

Another feature of the present invention is to provide a multi-chamber plasma processing system, comprising: a transport chamber; a load lock chamber operatively connected to the transport chamber, said load lock chamber having a vacuum gate valve and an atmospheric gate valve; a first process chamber mounted on the load lock chamber and operatively connected to the transport chamber, said first process chamber having only one gate valve, said gate valve positioned between the first process chamber and the transport chamber; and a substrate handling robot mounted within the transport chamber.

Yet another feature of the present invention is to provide a method for processing a substrate in a multi-chamber plasma processing system, the method comprising: providing a transport chamber; providing a load lock chamber having an atmospheric gate valve and a vacuum gate valve, said vacuum gate valve operatively connecting the load lock chamber to the transport chamber; providing a first process chamber mounted on the load lock chamber, said first process chamber having a single gate valve, said gate valve positioned between the first process chamber and the transport chamber, said gate valve operatively connecting the first process chamber to the transport chamber; providing a substrate handling robot that is mounted within the transport chamber; moving the substrate from the load lock chamber though the vacuum gate valve of the load lock chamber into the transport chamber using the substrate handling robot; and moving the substrate from the transport chamber though the gate valve of the first process chamber into the first process chamber using the substrate handling robot.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1 (Prior art) is a schematic block diagram showing a conventional processing system;

FIG. 2A is a schematic block diagram of a processing system of one embodiment according to the present invention; and

FIG. 2B is a schematic block diagram of a processing system of one embodiment according to the present invention.

Similar reference characters refer to similar parts throughout the several views of the drawings.

### DETAILED DESCRIPTION OF THE INVENTION

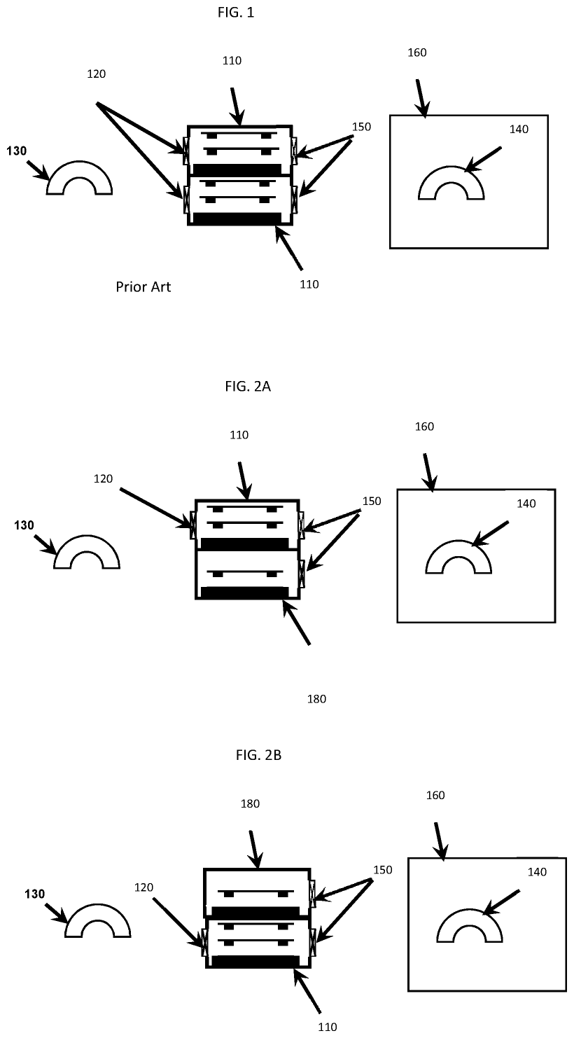

FIG. 1 is a schematic block diagram of a prior art system having two load lock chambers 110 stacked on top of each other. Each load lock chamber 110 has an atmospheric entry valve 120 on an entry side of the load lock chamber 110. In addition, each load lock chamber 110 has a vacuum valve 150 on a transport chamber 160 side of the load lock chamber 110. The prior art system has an atmospheric robot 130 for loading substrates into the respective load lock chamber 110 through the respective atmospheric entry valve 120. The system has a transport chamber 160 under vacuum with a vacuum robot 140 under vacuum for transporting substrates to and from the load lock chambers 110. Each load lock chamber 110 can receive a semiconductor substrate from atmosphere through the respective atmospheric entry valve 120. The respective load lock chamber 110 is then brought under vacuum once the semiconductor substrate is loaded into the load lock chamber 110. Then, the semiconductor substrate is transported into the transport chamber 160 via the vacuum robot 160. From the transport chamber 160, the semiconductor substrate is then transported to a process chamber (not shown) via the vacuum robot 160.

In the prior art, whenever a module is mounted to a load lock module, it is always another load lock module in that it always has both an atmospheric entry gate valve and a vacuum valve. Whereas, a typical process module only has a vacuum gate valve and no atmospheric entry gate valve. The reason the typical process module has only a vacuum gate valve is because it is better for process repeatability not to open the process module to atmosphere every time a substrate is loaded. Thus, the reason for having a load lock chamber that has an atmospheric entry gate valve so that the process module is not exposed to atmosphere.

In the present invention, an improved multi-chamber processing system is presented wherein a typical process module (one that has only a vacuum valve) is mounted to the load lock module. As shown in FIG. 2A, the improved multi-chamber processing system according to one embodiment of the present invention has a conventional process module 180 (a process module that has no atmospheric entry valve and only a vacuum valve) mounted to the bottom portion of a load lock chamber 110. In FIG. 2A, the load lock chamber 110 has an atmospheric entry valve 120 on an entry side of the load lock chamber 110 and a vacuum valve 150 on a transport chamber 160 side of the load lock chamber 110. The process module 180 (mounted to the underside of the load lock module 110) has only a vacuum valve 150 that is on the transport chamber side of the process module 180. The system of the present invention has an atmospheric robot 130 for loading substrates into the load lock chamber 110 through the atmospheric entry valve 120. The system of the present invention has a transport chamber 160 under vacuum with a vacuum robot 140 under vacuum for transporting substrates to and from the load lock chamber 110 and the process module 180. The vacuum robot is capable of transporting substrates to/from the load lock chamber 110 to the process module 180. Specifically, the load lock chamber 110 transfer a semiconductor substrate to/from atmosphere through the atmospheric entry valve 120. The load lock chamber 110 is brought under vacuum once the semiconductor substrate is loaded into the load lock chamber 110. Then, the semiconductor substrate is transported into the transport chamber 160 via the vacuum robot 160 through the vacuum valve 150. From the transport chamber 160, the semiconductor substrate can be transported to the process chamber 180 mounted to the bottom portion of the load lock chamber 110 or to any other process chamber (not shown) via the vacuum robot 160.

In the present invention, an improved multi-chamber processing system is presented wherein a typical process module (one that has only a vacuum valve) is mounted to the load lock module. As shown in FIG. 2B, the improved multi-chamber processing system according to one embodiment of the present invention has a conventional process module 180 (a process module that has no atmospheric entry valve and only a vacuum valve) mounted to the top portion of a load lock chamber 110. In FIG. 2B, the load lock chamber 110 has an atmospheric entry valve 120 on an entry side of the load lock chamber 110 and a vacuum valve 150 on a transport chamber 160 side of the load lock chamber 110. The process module 180 (mounted to the topside of the load lock module 110) has only a vacuum valve 150 that is on the transport chamber side of the process module 180. The system of the present invention has an atmospheric robot 130 for loading substrates into the load lock chamber 110 through the atmospheric entry valve 120. The system of the present invention has a transport chamber 160 under vacuum with a vacuum robot 140 under vacuum for transporting substrates to and from the load lock chamber 110 and the process module 180. The vacuum robot is capable of transporting substrates to/from the load lock chamber 110 to the process module 180. Specifically, the load lock chamber 110 transfer a semiconductor substrate to/from atmosphere through the atmospheric entry valve 120. The load lock chamber 110 is brought under vacuum once the semiconductor substrate is loaded into the load lock chamber 110. Then, the semiconductor substrate is transported into the transport chamber 160 via the vacuum robot 160 through the vacuum valve 150. From the transport chamber 160, the semiconductor substrate can be transported to the process chamber 180 mounted to the bottom portion of the load lock chamber 110 or to any other process chamber (not shown) via the vacuum robot 160.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

What is claimed is:

1. A multi-chamber plasma processing system, comprising:
a load lock chamber having a vacuum gate valve and an atmospheric gate valve;
a first process chamber mounted on the load lock chamber, said first process chamber having a single gate valve;
a transport chamber, said transport chamber operatively connected to the vacuum gate valve of the load lock chamber and operatively connected to the gate valve of the transport chamber; and
a substrate handling robot mounted within the transport chamber.

2. The multi-chamber plasma processing system according to claim 1, wherein the first process chamber is mounted to a top portion of the load lock chamber.

3. The multi-chamber plasma processing system according to claim 1, wherein the first process chamber is mounted to a bottom portion of the load lock chamber.

4. The multi-chamber plasma processing system according to claim 1, wherein the load lock chamber further comprising an internal elevator mounted within the load lock chamber.

5. The multi-chamber plasma processing system according to claim 1, wherein the first process chamber being adapted for gas chemistry deposition.

6. The multi-chamber plasma processing system according to claim 1, wherein the first process chamber being adapted for gas chemistry etching.

7. A multi-chamber plasma processing system, comprising:
a transport chamber;
a load lock chamber operatively connected to the transport chamber, said load lock chamber having a vacuum gate valve and an atmospheric gate valve;
a first process chamber mounted on the load lock chamber and operatively connected to the transport chamber, said first process chamber having only one gate valve, said gate valve positioned between the first process chamber and the transport chamber; and
a substrate handling robot mounted within the transport chamber.

8. The multi-chamber plasma processing system according to claim 7, wherein the first process chamber is mounted to a top portion of the load lock chamber.

9. The multi-chamber plasma processing system according to claim 7, wherein the first process chamber is mounted to a bottom portion of the load lock chamber.

10. The multi-chamber plasma processing system according to claim 7, wherein the load lock chamber further comprising an internal elevator mounted within the load lock chamber.

11. The multi-chamber plasma processing system according to claim 7, wherein the first process chamber being adapted for gas chemistry deposition.

12. The multi-chamber plasma processing system according to claim 7, wherein the first process chamber being adapted for gas chemistry etching.

13. A method for processing a substrate in a multi-chamber plasma processing system, the method comprising:
providing a transport chamber;
providing a load lock chamber having an atmospheric gate valve and a vacuum gate valve, said vacuum gate valve operatively connecting the load lock chamber to the transport chamber;
providing a first process chamber mounted on the load lock chamber, said first process chamber having a single gate valve, said gate valve positioned between the first process chamber and the transport chamber, said gate valve operatively connecting the first process chamber to the transport chamber;
providing a substrate handling robot that is mounted within the transport chamber;
moving the substrate from the load lock chamber though the vacuum gate valve of the load lock chamber into the transport chamber using the substrate handling robot; and
moving the substrate from the transport chamber though the gate valve of the first process chamber into the first process chamber using the substrate handling robot.

14. The method according to claim 13, wherein the first process chamber is mounted to a top portion of the load lock chamber.

15. The method according to claim 13, wherein the first process chamber is mounted to a bottom portion of the load lock chamber.

16. The method according to claim 13, further comprising loading the substrate through the atmospheric gate valve into the load lock chamber.

17. The method according to claim 13, further comprising loading the substrate onto an internal elevator mounted within the load lock chamber.

18. The method according to claim 13, further comprising depositing a material onto the substrate in the first process chamber using a plasma deposition process.

19. The method according to claim 13, further comprising etching a material from the substrate in the first process chamber using a plasma etch process.

20. The method according to claim 13, further comprising depositing a material onto the substrate in the first process chamber using a plasma deposition process and etching a material from the substrate in the first process chamber using a plasma etch process.
